(19) United States
(12) Patent Application Publication
(10) Pub. No.: US 2015/0244913 A1
(43) Pub. Date: Aug. 27, 2015

(54) TEST DEVICE

(71) Applicant: SUNMOON UNIVERSITY Industry-University Cooperation, Asan-si (KR)

(72) Inventor: Kuk Won KO, Seongnam-si (KR)

(73) Assignee: SUNMOON UNIVERSITY Industry-University Cooperation, Asan-si (KR)

(21) Appl. No.: 14/555,857

(22) Filed: Nov. 28, 2014

(30) Foreign Application Priority Data
Feb. 21, 2014 (KR) 10-2014-0020439

(51) Int. Cl. H04N 5/232; G01N 19/04; G01B 21/16; G01R 31/02

(52) U.S. Cl. CPC H04N 5/232; G01R 31/02; G01N 19/04; G01B 21/16; H04N 5/23212

(57) ABSTRACT

A test device in which a detector unit has a movable camera taking images of an object. The detector unit can obtain the position of the camera and acquire the position of the object based on the position of the camera.

### BACKGROUND OF THE INVENTION

1. Field of the Invention

The present invention relates to a device for automatically testing the bonding state of wires.

2. Description of the Related Art

A circuit or a semiconductor chip has a wire providing an electrical connection to a specific terminal.

The corresponding end of the wire is bonded to the specific terminal, in which the state of the bonding of the wire has a significant effect on the normal operation of the circuit or the semiconductor chip. It is therefore required to test whether or not the state of the bonding of the wire is reliable.

Korean Patent No. 0291780 disclosed a test device that tests the three-dimensional (3D) geometry of a bonding wire. However, this document did not disclose any method for testing the bonding state.

The information disclosed in the Background of the Invention section is only for the enhancement of understanding of the background of the invention, and should not be taken as an acknowledgment or as any form of suggestion that this information forms a prior art that would already be known to a person skilled in the art.

### RELATED ART DOCUMENT

Patent Document 1: Korean Patent No. 10-0291780

### SUMMARY OF THE INVENTION

Accordingly, the present invention has been made keeping in mind the above problems occurring in the related art, and the present invention is intended to propose a test device for testing the state of the bonding of a wire.

The objects of the present invention are not limited to the above-described objects but other objects can be clearly understood to a person skilled in the art in conjunction with the following description.

In order to achieve the above object, according to one aspect of the present invention, there is provided a test device including a detector unit. The detector unit includes a movable camera taking images of an object. The detector unit obtains a position of the camera and acquires a position of the object based on the position of the camera.

According to another aspect of the present invention, there is provided a test device including a detector unit acquiring a position of an object by taking images of the object using a movable camera. The position of the object is a value obtained by deducting a focal length of the camera from a first position of the camera in which a focus of photographing of the object is set.

According to a further aspect of the present invention, there is provided a test device including: a test unit testing a bonding state of a wire bonded to a circuit substrate by pulling the wire; and a detector unit determining a pulling point in which the wire is pulled using the test unit. The detector unit comprises a camera taking images of the wire while moving in a direction perpendicular to the circuit substrate. The detector unit acquires images of the wire in which two points upon which a focus of photographing is set become gradually closer to each other. The pulling point is determined to be one of the two points or to be a point in which the two points join together.

As set forth above, the test device according to the present invention can acquire the position of an object to be photographed based on the position of the movable camera. It is therefore possible to acquire the position of the object without a photographing device having a great depth of focus or a specific location device.

The position of the object acquired in this manner can be used when testing the object. In particular, when the test unit for determining the bonding state of the wire by pulling the wire is provided, it is possible to reliably determine the position in which the wire is caught by the test unit.

### BRIEF DESCRIPTION OF THE DRAWINGS

The above and other objects, features and advantages of the present invention will be more clearly understood from the following detailed description when taken in conjunction with the accompanying drawings, in which:

FIG. 1 is a schematic view showing a test device according to an exemplary embodiment of the invention;

FIG. 2 is a side-elevation view showing the test device according to an exemplary embodiment of the invention;

FIGS. 3 and 4 are schematic views showing the operation of the test device according to an exemplary embodiment of the invention; and

FIGS. 5 and 6 are other schematic views showing the operation of the test device according to an exemplary embodiment of the invention.

### DETAILED DESCRIPTION OF THE INVENTION

Reference will now be made in greater detail to an exemplary embodiment of the present invention, an example of which is illustrated in the accompanying drawings. Herein, the shapes and dimensions of parts illustrated in the drawings may be exaggerated for the clarity and convenience of explanation. In addition, the terminologies specifically defined considering the configurations and functions of the present invention may vary in compliance with the intention of users or operators or practices. The definitions of these terminologies should be construed based on the concept described herein.

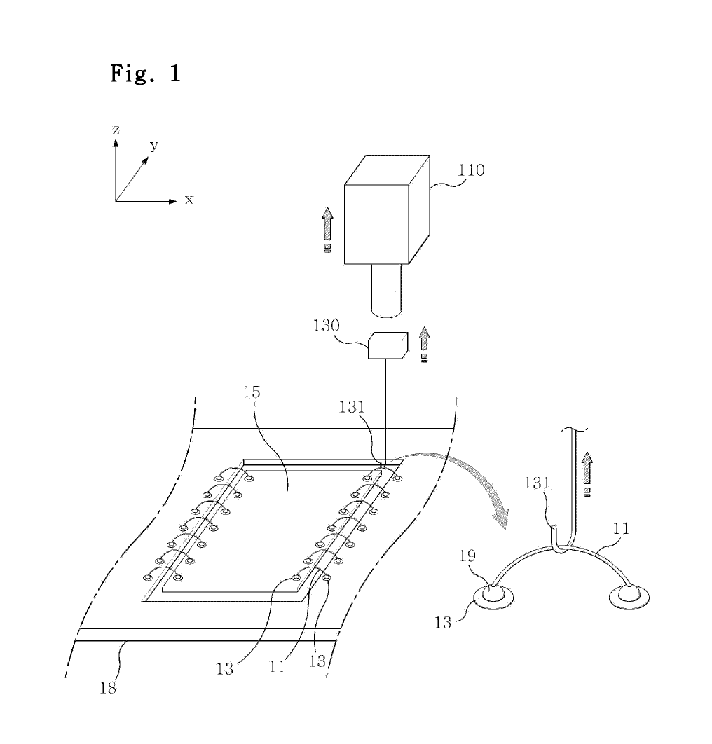

FIG. 1 is a schematic view showing a test device according to an exemplary embodiment of the invention.

The test device shown in FIG. 1 includes a detector unit 110.

The detector unit 110 is provided with a movable camera for taking an image from an object. The detector unit 110 can obtain the position of the camera, and can acquire the position of the object based on the position of the camera.

The object may be a variety of objects. For example, the object may be wires 11, opposite ends of which are connected to circuit terminals 13 via bonding 19. The bonding 19 may be implemented as solder bonding or the like.

Referring to FIG. 1, the circuit terminals 13 include the terminals 13 of semiconductor chips 15 and the terminals disposed on a substrate 18. The camera takes the images of the wires 11. The position of the camera or the position of the object can be determined based on the circuit terminals 13 or the substrate 18 or a device on which the circuit terminals 13 are disposed.

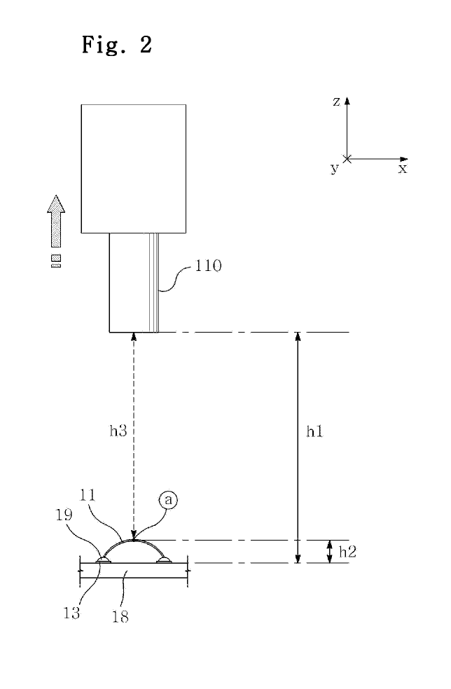

FIG. 2 is a side-elevation view showing the test device according to an exemplary embodiment of the invention.

Referring to FIG. 2, the camera can take an image of a first point \textcircled{a} of an object in order to acquire the position of the first point \textcircled{a} of the object.

In this case, when the focus of the photographing is set upon the first point \textcircled{a} on a first position h1 while the camera is moving, the detector unit 110 can acquire the position h2 of the first point \textcircled{a} using the first position h1. For reference, in FIG. 2, the first position h1 and the position h2 of the first point \textcircled{a} are determined at predetermined distances in the z axis from the substrate 18.

For example, the position of the object can be a value obtained by deducting the focal length of the camera from the first position of the camera, the focus of the photographing of which is set for the object. In FIG. 2, there is the following formula: h2=h1−h3, where the position of the object is the position h2 of the first point \textcircled{a} , the first position is h1, and the focal length is h3.

As described above, it is possible to determine whether or not the object is abnormal by acquiring the position of the first point \textcircled{a} using the movable camera.

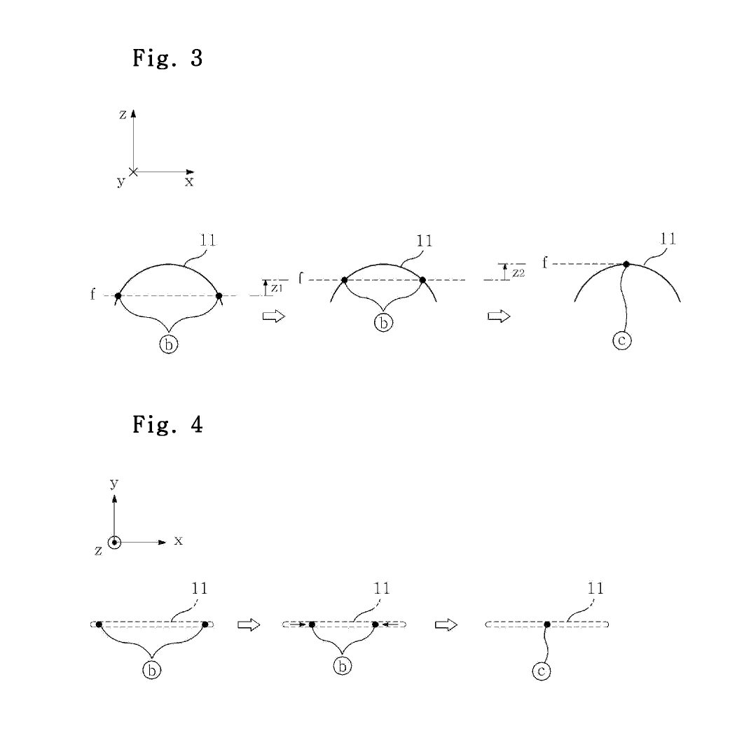

FIGS. 3 and 4 are schematic views showing the operation of the test device according to an exemplary embodiment of the invention. FIG. 3 is a side-elevation view, and FIG. 4 is a top plan view. FIG. 4 may show the image of a wire 11, which is substantially photographed by the camera. In FIG. 4, the dotted line indicates the portion of the wire where the focus of the photographing is not set, and dark dots indicate focal points \textcircled{b} or \textcircled{C} upon which the focus of the photographing is set.

When the object is the wire 11 with opposite ends thereof being connected to the circuit terminals 13 by the bonding 19, the wire 11 may protrude in the first direction (i.e. z axis direction) from the circuit terminals 13. The wire 11 may be in the shape of an arc when viewed from the side.

In this state, the camera can take an image of the wire 11 while moving in the first direction. It is preferable that the camera moves in the first direction from the position in which the focus for the circuit terminals 13 on which the wire 11 is disposed or the substrate 18 on which the circuit terminals 13 are disposed in order to determine whether or not the entire wire 11 is abnormal. The concept of the substrate may include a base substrate, such as a printed circuit board (PCB), or a circuit device, such as a semiconductor chip 15.

Accordingly, an image taken on the first position on the path along which the camera moves may have two focal points \textcircled{b} upon which the focus of the photographing is set. In FIG. 3, an imaginary line f indicates the focal points of the camera formed along the first direction, in which the two focal points \textcircled{b} are formed according to the geometry of the wire 11 protruding in the first direction. Even in the case in which the camera has moved by z1 in the first direction, there still are two focal points \textcircled{b}. In the state in which the two focal points \textcircled{b} are formed in this manner, the detector unit 110 can acquire the position of each focal point. It is possible to determine whether or not the wire 11 is abnormal using the position of each focal point that has been acquired in this manner. For example, in the case in which the position of the focal point \textcircled{b} that is initially set is 1 mm, when the position of the focal point \textcircled{b} measured by the detector unit 110 is 0.5 mm, the wire 11 will be determined to be defective.

It is also possible to test the state of the wire 11 without acquiring the position of each focal point \textcircled{b} . The distance between the focal points \textcircled{b} can vary in response to the movement of the camera. As the camera moves in the first direction, the distance between the focal points \textcircled{b} gradually decreases such that the focal points \textcircled{b} eventually join together. Referring to FIG. 2, it is appreciated that the distance between the focal points \textcircled{b} decreases as the camera moves by z1. In addition, when the camera moves by z2, the focal points \textcircled{b} join together, thereby forming a single focal point \textcircled{C}. When the camera moves further in the first direction, there is no image taken from the wire 11 in which the focus of the photographing is set. This phenomenon may occur when the wire 11 protrudes in the first direction in the shape of an arc.

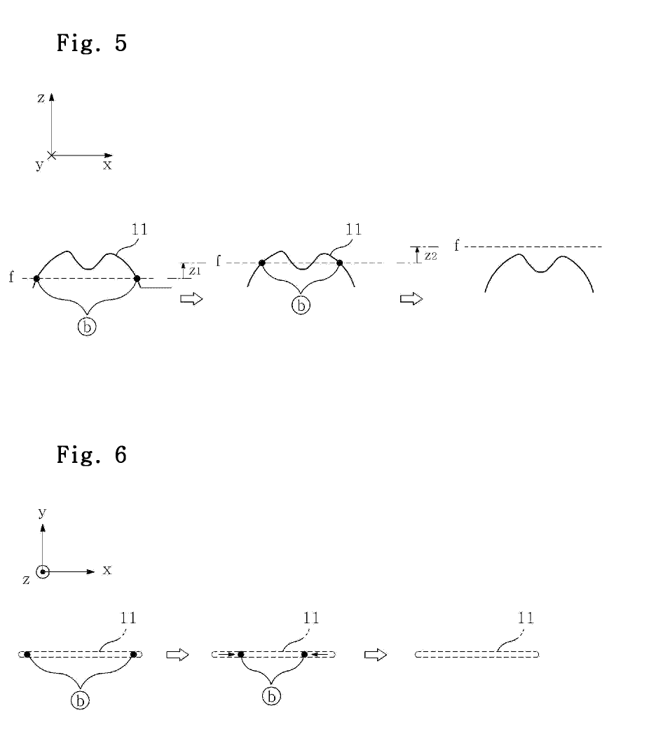

FIGS. 5 and 6 are other schematic views showing the operation of the test device according to an exemplary embodiment of the invention. FIGS. 5 and 6 show the state in which a wire 11, the geometry of which differs from the initially-designed geometry, is being tested. In this case, the initially-designed geometry may protrude in the first direction and have an arc-shaped side profile. In the wire 11 shown in FIGS. 5 and 6, by way of an example, the vertex portion thereof is depressed in the opposite direction from the first direction.

When the camera takes images of the wire 11 in this state while moving the first direction, at an early stage, two focal points \textcircled{b} will be formed as in the case shown in FIGS. 3 and 4. This is the same as in the case in which the camera has moved by z1. However, when the camera has moved by z2, the two focal points \textcircled{b} do not join together since the wire 11 is depressed. Consequently, the focal point \textcircled{C} shown in FIGS. 3 and 4 is not formed.

Referring to the images taken using the camera shown in FIG. 6, the two focal points \textcircled{b} become gradually closer, but do not join together, in which state the focal point \textcircled{C} upon which the focus is set does not appear in the images. It is therefore possible to determine that the vertex portion of the wire 11 is depressed by referring to the images in FIG. 6. Accordingly, the detector unit 110 can determine whether or not the wire 11 is defective based on variations in the distance between the focal points.

Furthermore, it is possible to determine whether or not the wire 11 is defective based on only the focal point \textcircled{C} although the result is rather rough.

Specifically, a single focal point upon which the focus of the photographing of the wire 11 is set may exist on an image taken on the first position on the path along which the camera moves. The focal point at this time may be the focal point \textcircled{C} that has been discussed above. The detector unit 110 may acquire the position of the focal point \textcircled{C} while disregarding the other focal points \textcircled{b}.

In addition, the detector unit 110 determines the wire 11 to be normal if the position of the focal point \textcircled{C} satisfies a predetermined position and determines the wire 11 to be defective otherwise.

As an alternative method, it is possible to determine whether or not the wire 11 is abnormal based on only whether or not the focal point \textcircled{C} is present on the images. The defector unit 110 may determine the wire 11 to be normal if the focal point \textcircled{C} is present on an image from among images taken by the camera and determine the wire 11 to be defective if the focal point \textcircled{C} is not present on any one of the images taken by the camera.

The position of the object acquired by the detector unit 110 may be used when testing the state of another object. It has been described above of the configuration of determining whether or not the geometry of the wire 11 is normal when the object to be tested is the wire 11.

When the object is the wire 11, the test device may be provided with a test unit 130 that tests the state of the bonding of the wire 11 by pulling the wire 11 connected to the substrate 18 via the bonding 19. Here, the detector unit 110 may determine a point in which the wire 11 is pulled toward the test unit 130.

Returning to FIG. 1, the test unit 130 can pull the wire 11 in the first direction. The first direction may perpendicular to the substrate 18.

The test unit 130 may be provided with a hook 131 to catch the wire 11. The position of the wire 11 that is caught by the hook 131, i.e. the position in which the wire 11 is pulled, is important. The test unit 130 pulls the wire 11 in order to test the reliability of adhesion of the bonding 19. It is required to pull the wire 11 such that the same force is applied to opposite ends of the wire 11. When the hook 131 catches a portion of the wire 11 that is offset toward any one end, a greater amount of force is applied to the offset portion, in which condition a test cannot be performed properly. In addition, the state of the bonding 19 may be released due to the application of an excessive amount of force.

The detector unit 110 can acquire images from the wire 11 in which the two focal points \textcircled{b} upon which the focus is not set become gradually closer to each other and join together into the single focal point \textcircled{C} while the camera is moving. In this case, the pulling point, i.e. the point in which the wire 11 is pulled, may be determined to be one of the two focal points \textcircled{b} or to be the focal point \textcircled{C} that is formed through the joining of the two focal points \textcircled{b}. The pulling point determined in this manner may be the point that causes the same tension to be applied to opposite ends of the wire 11 on which the bonding 19 is provided.

When the pulling point is determined to be within the section between the two points \textcircled{b}, it is unnecessary to move the camera to the position in which the focal point \textcircled{C} is acquired. Consequently, the point of time when the pulling point is determined may be made earlier

When the pulling point is determined to be the single focal point \textcircled{C}, the camera is moved to the position in which the focal point \textcircled{C} is acquired. In this case, it is possible to perform the test on whether or not the wire 11 is abnormal although the point of time when the pulling point is determined is rather delayed. In particular, in the case in which the wire 11 is abnormal as in FIG. 5, when the test unit 130 is disposed in the section between the two points \textcircled{b}, the wire 11 may not be caught by the hook 131 of the test unit 130. However, when the pulling point is determined to the focal point \textcircled{C}, the abnormality of the wire 11 can be additionally tested. Consequently, the wire 11 can be reliably caught by the hook 131 of the test unit 130.

It is required to clearly and visually recognize the wire 11 in order to catch the wire 11 with the hook 131 of the test unit 130. For this, an expensive camera having a great depth of focus may be used. However, the high depth of focus may sometimes cause the accurate location of the wire 11 to be difficult instead. According to the invention, it is possible to accurately acquire the position in which wire 11 is to be caught by the test unit 130 using an inexpensive camera having a small depth of focus. It is also possible to accurately acquire the position of the wire 11.

Although the exemplary embodiments of the present invention have been described for illustrative purposes, those skilled in the art will appreciate that various modifications, additions and substitutions are possible, without departing from the scope and spirit of the present invention as disclosed in the accompanying claims.

What is claimed is:

1. A test device comprising:
a detector unit comprising a movable camera taking images of an object,
wherein the detector unit obtains a position of the camera and acquires a position of the object based on the position of the camera.

2. The test device according to claim 1, wherein
the object comprises a wire having an end bonded to a circuit terminal,
the camera takes images of the wire, and
a position of the camera or a position of the object is determined based on the circuit terminal or a substrate on which the circuit terminal is disposed.

3. The test device according to claim 1, wherein
the camera takes an image of a first point of the object, and
if a focus of photographing is set upon the first point on a first position while the camera is moving, the detector unit acquires a position of the first point based on the first position.

4. The test device according to claim 1, wherein
the object comprises a wire having opposite ends bonded to circuit terminals, wherein the wire protrudes in a first direction from the circuit terminals,
the camera takes images of the wire while moving in the first direction,
an image taken on a first position on a path along which the camera moves has two focal points upon which a focus of photographing is set, and
the detector unit acquires positions of the focal points.

5. The test device according to claim 4, wherein
a distance between the focal points varies in response to the movement of the camera, and
the detector unit determines whether or not the wire is abnormal based on variations in the distance between the focal points.

6. The test device according to claim 4, further comprising a test unit testing a bonding state of the wire by pulling the wire in the first direction, wherein the test unit pulls a section of the wire between the two focal points in the first direction.

7. The test device according to claim 1, wherein
the object comprises a wire having opposite ends bonded to circuit terminals, wherein the wire protrudes in a first direction from the circuit terminals,
the camera takes images of the wire while moving in the first direction,
an image taken on a first position on a path along which the camera moves has a single focal point upon which a focus of photographing is set, and
the detector unit acquires a position of the focal point.

8. The test device according to claim 7, further comprising a test unit testing a bonding state of the wire by pulling the wire in the first direction, wherein the test unit pulls the wire at the focal point.

9. A test device comprising a detector unit acquiring a position of an object by taking images of the object using a movable camera, wherein the position of the object is a value obtained by deducting a focal length of the camera from a first position of the camera in which a focus of photographing of the object is set.

10. A test device comprising:
a test unit testing a bonding state of a wire bonded to a circuit substrate by pulling the wire; and
a detector unit determining a pulling point in which the wire is pulled using the test unit, wherein
the detector unit comprises a camera taking images of the wire while moving in a direction perpendicular to the circuit substrate,
the detector unit acquires images of the wire in which two points upon which a focus of photographing is set become gradually closer to each other, and
the pulling point is determined to be one of the two points or to be a point in which the two points join together.
